(19) United States
(12) Patent Application Publication
(10) Pub. No.: US 2024/0012215 A1
(43) Pub. Date: Jan. 11, 2024

(54) COUPLING MICROLEDS TO OPTICAL COMMUNICATION CHANNELS

(71) Applicant: AvicenaTech Corp., Mountain View, CA (US)

(72) Inventors: Robert Kalman, Mountain View, CA (US); Bardia Pezeshki, Mountain View, CA (US); Alexander Tselikov, Mountain View, CA (US); Cameron Danesh, Mountain View, CA (US)

(73) Assignee: AvicenaTech Corp., Mountain View, CA (US)

(21) Appl. No.: 18/472,573

(22) Filed: Sep. 22, 2023

Related U.S. Application Data
(63) Continuation of application No. 17/229,485, filed on Apr. 13, 2021.
(60) Provisional application No. 63/009,106, filed on Apr. 13, 2020.

(51) Int. Cl. G02B 6/42; G02B 6/43

(52) U.S. Cl. CPC G02B 6/4214; G02B 6/43; G02B 6/4295; G02B 6/4246

(57) ABSTRACT

Light from one or more microLEDs may be coupled into multiple waveguide cores. Parabolic reflectors, truncated parabolic reflectors, and encapsulants may be used to increase fraction of emitted light coupled into the waveguide cores.

### CROSS REFERENCE TO RELATED APPLICATION

This application claims the benefit of the filing date of U.S. Provisional Patent Application No. 63/009,106, filed on Apr. 13, 2020, the disclosure of which is incorporated by reference herein.

### FIELD OF THE INVENTION

The present invention relates generally to optical communication systems, and more particularly to coupling of microLEDs to communication channels in optical communication systems.

### BACKGROUND OF THE INVENTION

Desires for high-performance computing and networking is ubiquitous and seemingly ever-present. Prominent applications include data center servers, high-performance computing clusters, artificial neural networks, and network switches.

For decades, dramatic integrated circuit (IC) performance and cost improvements were driven by shrinking transistor dimensions combined with increasing die sizes, summarized in the famous Moore's Law. Transistor counts in the billions have allowed consolidation onto a single system-on-a-chip (SoC) of functionality that was previously fragmented across multiple ICs.

However, the benefits of further transistor shrinks are decreasing dramatically as decreasing marginal performance benefits combine with decreased yields and increased per-transistor costs. Independent of these limitations, a single IC can only contain so much functionality, and that functionality is constrained because the IC's process cannot be simultaneously optimized for different functionality, e.g. logic, DRAM, and I/O.

In fact, there are significant benefits to “de-integrating” SoCs into smaller “chiplets”, including:

The process for each chiplet can be optimized to its function, e.g. logic, DRAM, high-speed I/O, etc.

Chiplets are well-suited to reuse in multiple designs.

Chiplets are less expensive to design.

Chiplets have higher yield because they are smaller with fewer devices.

There is, however, a major drawback to chiplets compared to SoCs: use of chiplets generally requires far more chip-to-chip connections. Compared to the on-chip connections between functional blocks in SoCs, chip-to-chip connections are typically much less dense and require far more power (for example normalized as energy per bit).

### BRIEF SUMMARY OF THE INVENTION

Some embodiments provide optical interconnects (connecting between chips and/or chiplets) based on microLED sources. A microLED may be generally defined as an LED with a diameter of <100 um in some embodiments, <20 um in some embodiments, and <1 um in some embodiments and can be made with diameters <1 um. In some embodiments the microLED sources can support optical links with lengths of >1 m at >1 Gbps with lower drive power than comparable electrical links and very high density.

One of the key challenges in usefully applying microLEDs to optical communications is coupling the microLEDs with high efficiency to optical communication channels, whether that communication channel comprises, or in some embodiments consists of, waveguides, free-space, or some combination of the two. Discussed herein are embodiments for coupling microLEDs to optical communication channels, which may be practical high performance techniques.

Some embodiments provide, in a system optically coupling two integrated circuit chips, the system including transceiver circuitry for each of the two integrated circuit chips, the system including optical elements comprising: a microLED to be driven by the transceiver circuitry; a photodetector to provide electrical signal carrying received information to the transceiver circuitry; and an array of multiple waveguide cores, including a plurality of waveguide cores configured to receive light emitted by the microLED.

These and other aspects of the invention are more fully comprehended upon review of this disclosure.

### BRIEF DESCRIPTION OF THE DRAWINGS

FIG. 1a shows the spatial and angular width of an LED of size xₒ×yₒ and an angular spectrum occupying −π to π radians in the θ direction and 0 to π/2 radians in the φ direction (using spherical coordinates).

FIG. 1B shows that the θ and φ ranges can be decreased.

FIG. 2a shows the angular spectrum of an LED.

FIG. 2b shows the angular spectrum of the LED divided into smaller regions.

FIG. 2c shows an example implementation of division of angular spectrum of an LED into multiple waveguides.

FIG. 3a shows the use of a lens to couple light from an LED to a waveguide.

FIG. 3b shows the use of a lens to couple light from an LED to a 2D array of waveguides.

FIG. 3c shows the use of a lens to couple light from an LED into a free-space propagation region.

FIG. 4a shows the use of a parabolic reflector to efficiently capture light emitted at large angles from the LED and couple it into an output waveguide.

FIG. 4b shows a parabolic reflector used to couple light from an LED into a 2D array of output waveguides.

FIG. 4c shows a parabolic reflector used to couple light from an LED into a free-space propagation region.

FIG. 5a shows a truncated parabolic reflector where an LED sits in a flat truncated bottom area of the reflector.

FIG. 5b shows a truncated parabolic reflector used to couple light from an LED into a 2D array of output waveguides.

FIG. 5c shows a truncated parabolic reflector used to couple light from an LED into a free-space propagation region.

FIG. 6a shows a microLED at a base of a truncated parabolic reflector, with a lens between the microLED and a waveguide above the microLED and reflector.

FIG. 6b shows a hybrid lens—truncated parabolic reflector used to couple light from an LED into a 2D array of output waveguides.

FIG. 6c shows a hybrid lens—truncated parabolic reflector used to couple light from an LED into a free-space propagation region.

FIG. 7a shows an LED facing down toward the trough of a parabolic reflector.

FIG. 7b shows the inverted LED with a parabolic reflector of FIG. 7a coupling to a 2D array of waveguides.

FIG. 7c shows the inverted LED with a parabolic reflector of FIG. 7a used to couple light from an LED into a free-space propagation region.

FIGS. 8a and 8b show side and top views, respectively, of an embodiment which uses a parabolic reflector to efficiently capture light emitted vertically or laterally by an LED and couple the light into an output waveguide.

FIG. 8c shows a top view of a parabolic reflector used to couple light from an LED into a 1D array of output waveguides.

FIG. 9a shows an example of LED encapsulation.

FIG. 9b shows encapsulant interposed between the microLED and a waveguide medium.

FIG. 9c shows encapsulant as an approximately cylindrical column that continues up to a top of the waveguide.

FIG. 10a shows a curved reflector formed on one end of a microLED.

FIG. 10b shows a lens formed on the end of a microLED.

FIG. 10c shows a top view of a microLED mounted on a substrate, with a curved reflector on the side of the LED.

FIG. 11a shows an array of microLEDs, each with its associated coupling assembly, coupled into a free-space propagation region.

FIG. 11b shows an example of free-space optical elements (FSOEs) of a free-space propagation region.

FIG. 12 is a block diagram showing an electrical architecture including a first optically-interconnected IC.

FIGS. 13a-c show different physical configurations for implementing a transceiver subsystem, in accordance with aspects of the invention.

FIG. 14 shows integration of planar optical links within a package, in accordance with aspects of the invention.

FIG. 15 shows integration of optical links within an interposer and package, in accordance with aspects of the invention.

### DETAILED DESCRIPTION

A microLED is made from a p-n junction of a direct-bandgap semiconductor material. A microLED is distinguished from a semiconductor laser (SL) in the following ways: (1) a microLED does not have an optical resonator structure; (2) the optical output from a microLED is almost completely spontaneous emission whereas the output from a SL is dominantly stimulated emission; (3) the optical output from a microLED is temporally and spatially incoherent whereas the output from a SL has significant temporal and spatial coherence; (4) a microLED is usually designed to be operated down to a zero minimum current, whereas a SL is designed to be operated above a minimum threshold current, which is typically at least 1 mA.

A microLED may be distinguished from a standard LED by having an emitting region of equal to or less than 20 μm×20 μm. MicroLEDs generally have small etendue, allowing them to be efficiently coupled into small waveguides and/or imaged onto small photodetectors. For convenience, the following discussion will generally mention LEDs. It should be recognized, however, that the discussion pertains to microLEDs, which may be considered a particular type of LED.

LEDs, including microLEDs emit in a Lambertian pattern; light is emitted into a full half-sphere of 2π steradians. This wide angular spectrum is poorly matched to the limited numerical aperture (NA) of a waveguide. A challenge in coupling a microLED to a small waveguide is to address this NA mismatch.

The product of the spatial and angular aperture of an LED is captured in its etendue. The etendue of an LED generally cannot be reduced; generally it can only be preserved or increased. This implies, for instance, that the coupling from an LED to a single-mode waveguide is very low, since a single-mode waveguide has a very low etendue.

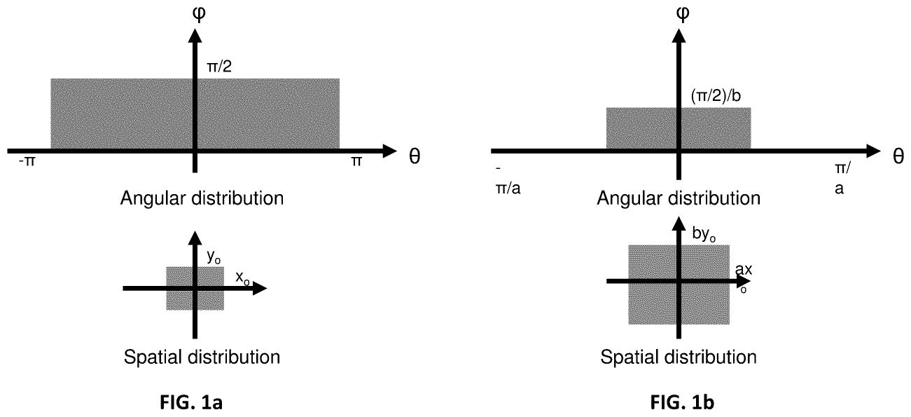

FIG. 1a shows the spatial and angular width of an LED of size xₒ×yₒ and an angular spectrum occupying −π to π radians in the θ direction and 0 to π/2 radians in the φ direction (using spherical coordinates). Through the use of curved optical surfaces, whether refractive (e.g. a lens) or reflective (e.g. a curved mirror), the spatial and angular distribution widths of an LED can be traded off. FIG. 1B shows that the θ and φ ranges can be decreased by factors of a and b, respectively, at the expense of increasing the x and y spatial width by factors of a and b, respectively (a>1, b>1).

The ability to reduce angular width by increasing spatial width is especially powerful for very small microLEDs. For instance, light from a 1 um×1 um microLED can be efficiently coupled to a 4 um×4 um waveguide with an NA of 0.25 (which is quite practical for a multimode waveguide) if appropriate curved optical elements are used. This is discussed below.

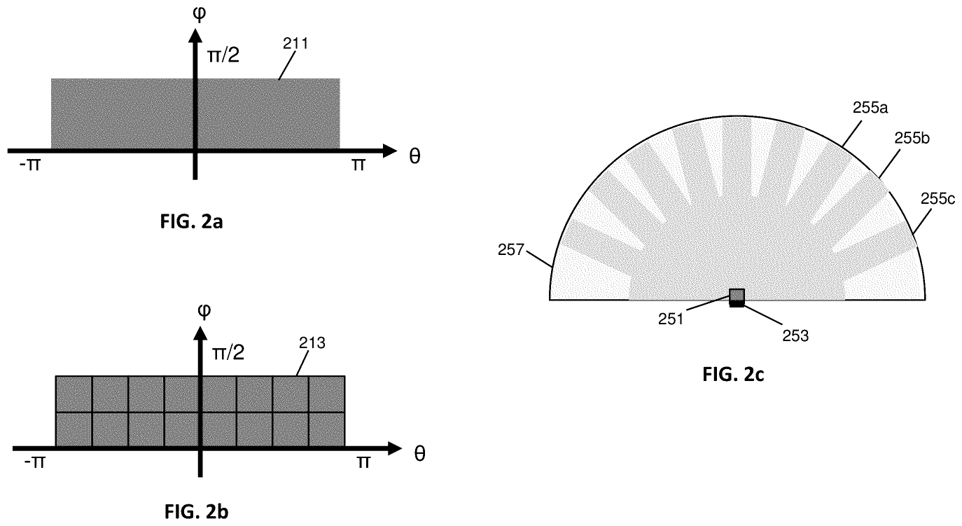

It can be useful to launch light from an LED into multiple output waveguides. This allows a signal modulated on the LED to be broadcast to multiple destinations, which is useful in many processing architectures. The broad angular spectrum of an LED is well-suited to this broadcast functionality. FIG. 2a shows the angular spectrum 211 of an LED. FIG. 2b shows that the angular spectrum of an LED can be divided into smaller regions, for example a region 213, each of which has an angular spectrum that is well-matched to the characteristics of an output waveguide. FIG. 2c shows how this can be implemented with a 1-dimensional (1D) or 2-dimensional (2D) array of output waveguides. In FIG. 2c, a microLED 251 has a bottom reflector 253 to assist in directing light generally towards multiple waveguides, for example waveguide cores 255a-c. The waveguide cores are surrounded by cladding 257. In the 2D case, the second dimension of the output waveguide array is into the page.

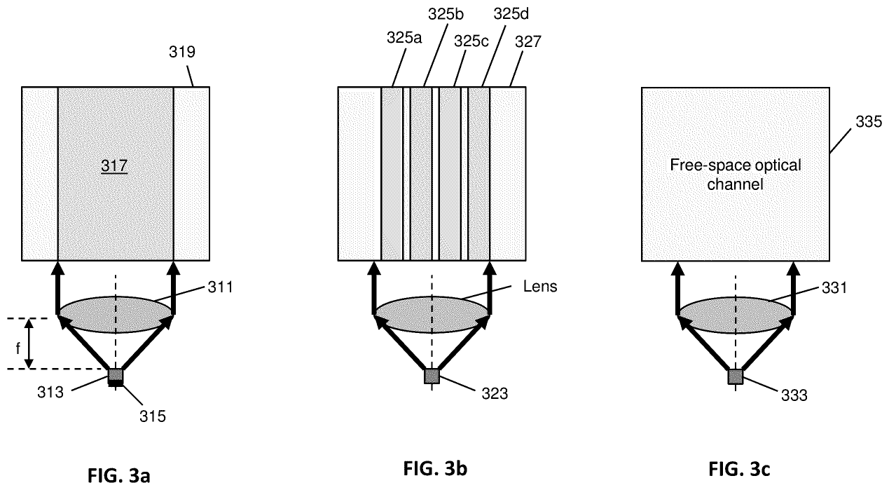

FIG. 3a shows the use of a lens 311 to couple light from an LED to a waveguide, with FIG. 3a showing a microLED 313, and the waveguide as including a waveguide core 317 surrounded by waveguide cladding 319. A bottom reflector 315 is on a bottom of the microLED, away from the lens, to assist in directing light towards the lens. The lens is used to trade off the angular and spatial width of the LED's emission. If the lens diameter is larger than that of the LED, and for example located approximately one focal length from the LED, all as illustrated in FIG. 3a, the angular spectrum at the output of the lens is significantly decreased from that at the lens input and can be efficiently coupled to a waveguide matched to the diameter and NA of the output light from the lens.

FIG. 3b shows the use of a lens 321 to couple light from an LED, a microLED 323 as illustrated in FIG. 3b, to a 2D array of waveguides. The array of waveguides include a plurality of parallel waveguide cores 325a-d, surrounded by waveguide cladding 327. If the spacing between waveguides is small compared to the core diameter, most of the light at the lens output will be coupled into the waveguides. For a lens of a given diameter, the waveguides can be smaller compared to the single output waveguide case. The intensity at the center generally will be somewhat higher than that at the edges. If desired, the center waveguide can be made narrower than the waveguides at the edges to equalize the power coupled into each waveguide.

FIG. 3c shows the use of a lens 331 to couple light from an LED, a microLED 333 in FIG. 3c, into a free-space propagation region 335. Such a region may contain a variety of refractive, reflective, and absorptive elements including lenses, holographic optical elements, and mirrors.

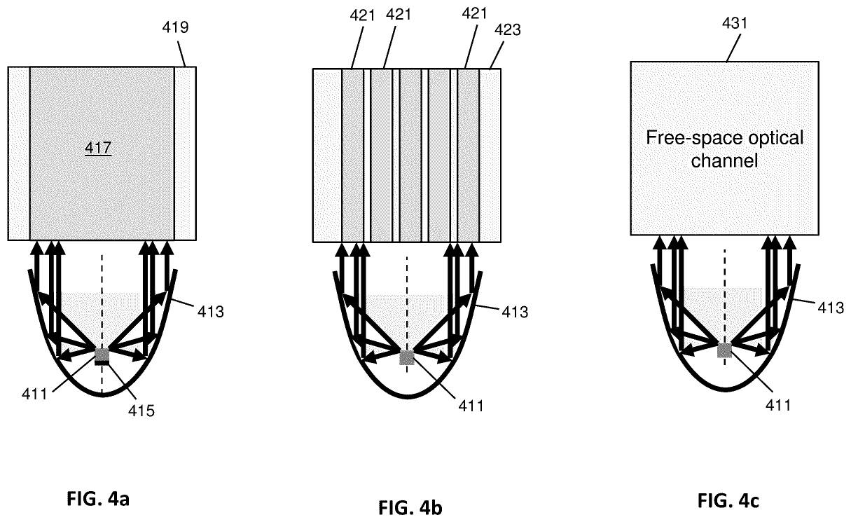

Practical lenses with f-numbers much less than 1 are generally difficult to realize. This implies that the lenses in FIGS. 3a-c may fail to capture a large amount of the LEDs output power. FIG. 4a shows the use of a parabolic reflector to efficiently capture light emitted at large angles from the LED and couple it into an output waveguide. FIG. 4a shows a microLED 411 at approximately a focus of a parabolic reflector 413. The microLED has a reflector 415 at its bottom, with a top of the microLED facing a waveguide comprised of a waveguide core 417 surrounded by waveguide cladding 419. Note that, depending on the LED design, the LED may emit significant lateral light from edge emission as well as vertical light from surface emission, and the parabolic reflector captures both of these well. As the parabola is made deeper and deeper, the angular spectrum of the output light is decreased while the size of the output optical distribution increases, which is the expected trade-off. To produce an output angular spectrum that can be efficiently coupled to a waveguide with an NA of <0.3, the parabola may get quite deep.

FIG. 4b shows a parabolic reflector used to couple light from an LED into a 2D array of output waveguides. FIG. 4b is similar to FIG. 4a, with the microLED 411 at about a focus of the parabolic reflector 413. Compared to FIG. 4a, however, FIG. 4b includes a plurality of waveguide cores 421 surrounded by waveguide cladding 423, instead of a single waveguide core surrounded by waveguide cladding. The intensity distribution at the waveguide inputs is a bit complicated because there is overlap of reflected and unreflected rays. There is also a contribution from the lateral emission. The power into each waveguide can be equalized by varying the waveguide area in inverse proportion to the optical intensity at its input.

FIG. 4c shows a parabolic reflector 413 used to couple light from an LED, for example the microLED 413 into a free-space propagation region 431. Such a region may contain a variety of refractive, reflective, and absorptive elements including lenses, holographic optical elements, and mirrors.

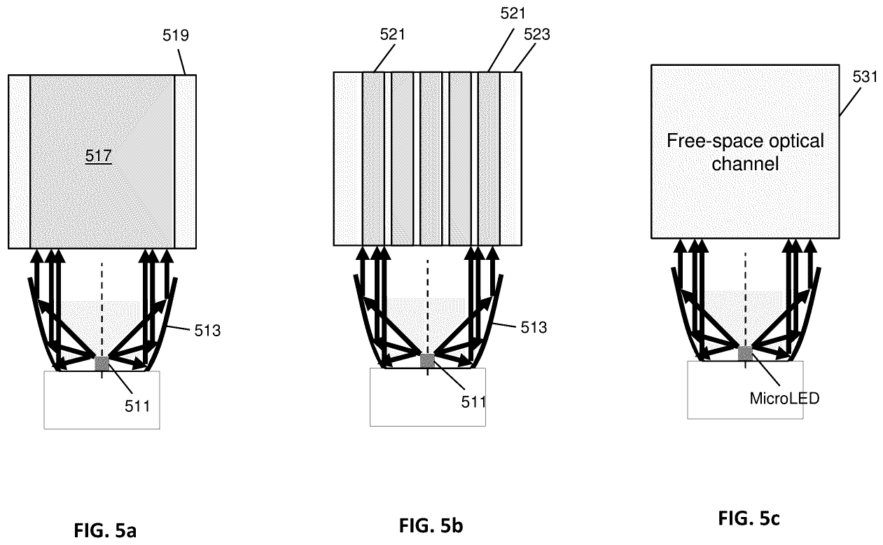

If the lateral emission from the LED is small (or the LED is oriented such that emission is small in directions normal to propagation direction from the LED to the waveguide), there may be reduced or no need for the bottom part of the parabolic reflector because light is not substantially emitted at angles beyond the LED surface parallel (assuming the LED has a rear reflector). FIG. 5a shows a truncated parabolic reflector where an LED sits in a flat truncated bottom area of the reflector. In FIG. 5a, the LED is a microLED 511. Walls of the truncated parabolic reflector 513 extend upward from about a bottom surface of the microLED. A multicore waveguide, with multiple waveguide cores 515 surrounded by waveguide cladding 517, is above the microLED. The use of a truncated parabolic reflector may simplify fabrication and assembly compared to use of the full parabolic reflector.

FIG. 5b shows a truncated parabolic reflector used to couple light from an LED into a 2D array of output waveguides. In FIG. 5b, the microLED 511 is at about a base of the truncated parabolic reflector 513. A multicore waveguide, with multiple waveguide cores 521 surrounded by waveguide cladding 523, is above the microLED. As is the case with lens-based coupling, the intensity in the center will tend to be higher than at the edges. If desired, the center waveguide can be made narrower than the waveguides at the edges to equalize the power coupled into each waveguide.

FIG. 5c shows a truncated parabolic reflector used to couple light from an LED into a free-space propagation region. FIG. 5c also shows the microLED 511 at about a base of the truncated parabolic reflector 513. A free-space propagation region 531 is above the microLED and truncated parabolic reflector. The free-space propagation region may contain a variety of refractive, reflective, and absorptive elements including lenses, holographic optical elements, and mirrors.

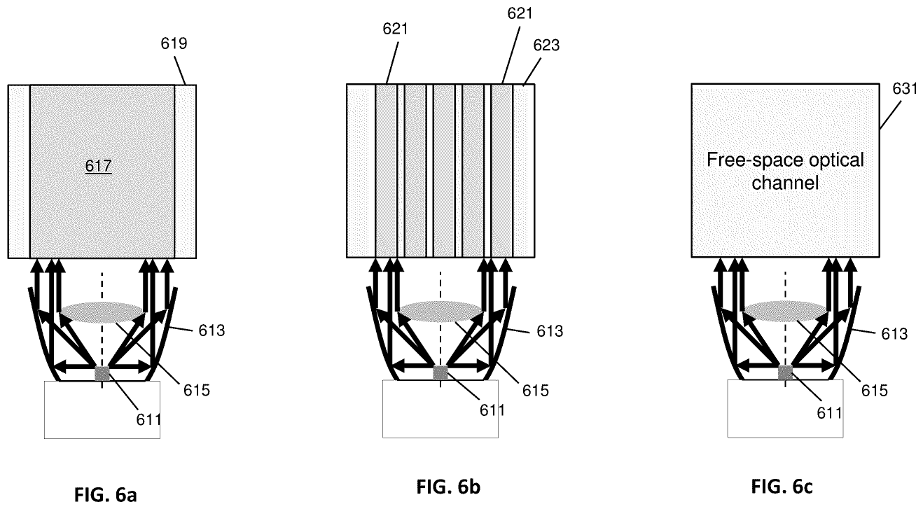

To reduce otherwise desired depth of the parabolic reflector, for example in order to make its fabrication more practical, a lens and parabolic reflector can be used together in a hybrid assembly. FIG. 6a shows a microLED 611 at a base of a truncated parabolic reflector 613, with a lens 615 between the microLED and a waveguide above the microLED and reflector. The waveguide includes a waveguide core 617 surrounded by waveguide cladding 619. Rays closer to the LED surface normal are bent by the lens, while those at angles exceeding the lens's NA are reflected by the parabola. This hybrid approach provides very high potential coupling efficiency to a waveguide while requiring much less depth in the parabolic reflectors.

FIG. 6b shows a hybrid lens—truncated parabolic reflector used to couple light from an LED into a 2D array of output waveguides. In FIG. 6b, the arrangement of the microLED 611, truncated parabolic reflector 613 and lens 615 is as discussed with respect to FIG. 6a. The embodiment of FIG. 6b, however, replaces the waveguide with a multicore waveguide, having a plurality of waveguide cores 621 surrounded by waveguide cladding 623. As is the case with lens-based coupling, the intensity in the center will tend to be higher than at the edges. If desired, the center waveguide can be made narrower than the waveguides at the edges to equalize the power coupled into each waveguide.

FIG. 6c shows the hybrid lens—truncated parabolic reflector used to couple light from an LED, which may be the microLED 611, into a free-space propagation region 631. Such a region may contain a variety of refractive, reflective, and absorptive elements including lenses, holographic optical elements, and mirrors.

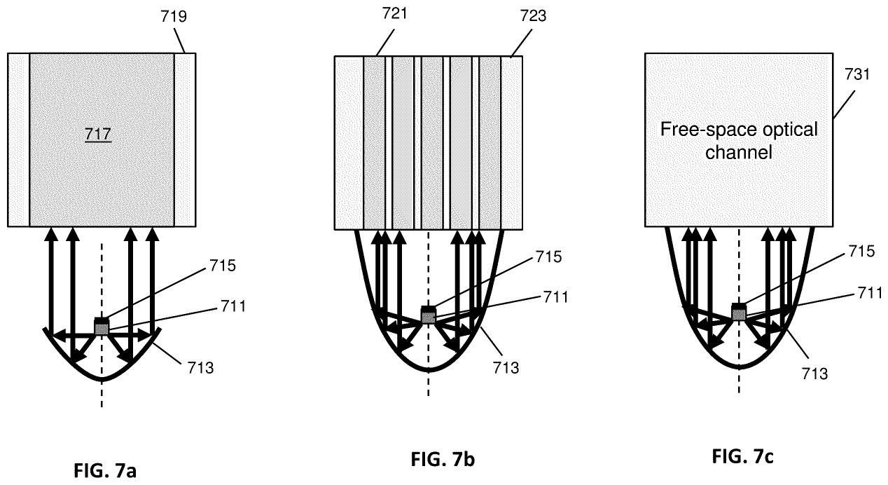

FIG. 7a shows an LED, which may be a microLED 711, facing down toward the trough of a parabolic reflector 713. In other words, primarily light is emitted from the LED towards the trough, and the LED may have a reflector 715 on a side away from the trough. In FIG. 7a, light is reflected from the parabolic reflector towards a waveguide core 717, which is surrounded by waveguide cladding 719. This approach may use a parabola of only modest depth and can capture the LED's light very efficiently. Some of the light reflected by the parabola is occluded by the LED, but if the beam size is being significantly expanded then the associated occlusion loss can be quite small. For instance, if the light is expanded 4× in each transverse dimension then the occlusion loss can be in the range of 1/16 (0.3 dB) of the optical power. The optical power distribution will be similar to that from a lens, with the exception that the very center will be notched out by the shadow of the LED.

FIG. 7b shows the inverted LED with a parabolic reflector of FIG. 7a coupling to a 2D array of waveguides. The array of waveguides is shown in FIG. 7b as including a plurality of waveguide cores 721 surrounded by waveguide cladding 723. If the spacing between waveguides is small compared to the core diameter, most of the light at the lens output will be coupled into the waveguides. For a given parabola size, the waveguides can be smaller compared to the single output waveguide case. The intensity of light at the very center will be notched out by the shadow of the LED, but beyond that shadow, the intensity closer to the center will be higher than that at the edges. If desired, the waveguide areas can be varied in inverse proportion to the intensity at their inputs to equalize the power coupled into each waveguide.

FIG. 7c shows the inverted LED with a parabolic reflector of FIG. 7a used to couple light from an LED into a free-space propagation region 731. Such a region may contain a variety of refractive, reflective, and absorptive elements including lenses, holographic optical elements, and mirrors.

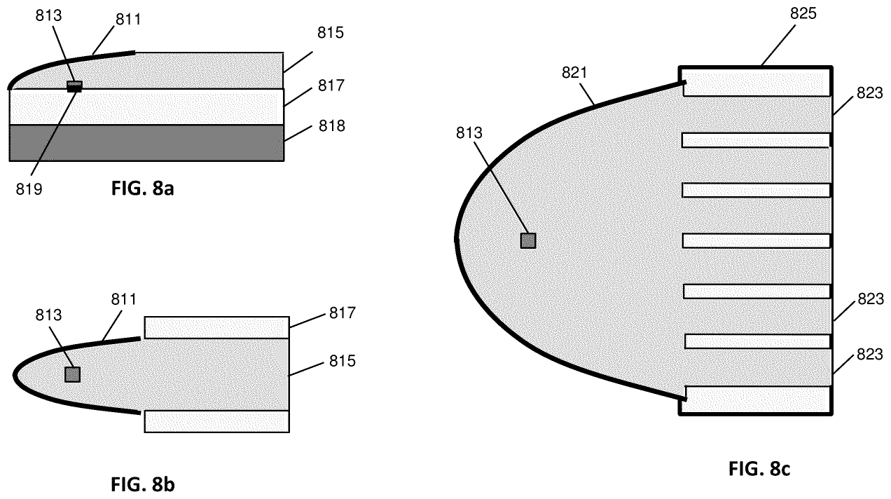

FIGS. 8a and 8b show side and top views, respectively, of an embodiment which uses a parabolic reflector 811 to efficiently capture light emitted vertically or laterally by an LED, which may be a microLED 813, and couple the light into an output waveguide. In the embodiment of FIGS. 8a and 8b, the microLED is in a waveguide core 815, both of which are on waveguide cladding 817, with the waveguide cladding also being on sides of the waveguide core. The waveguide cladding is shown as on a substrate 818. A bottom reflector 819 is on a bottom of the microLED. The microLED is placed near an end of the waveguide core, with the parabolic reflector on top of a correspondingly shaped end of the waveguide core. The horizontal and vertical curvature of the reflector can be different to accommodate a waveguide with different height and width. The horizontal curvature can be defined using two-dimensional lithographic methods, while the vertical curvature can be defined by thermal reflow, by multi-layer two-dimensional lithography, or by three-dimensional lithography.

As shown in FIGS. 8a,b, the LED can be embedded in the waveguide itself. This provides the benefit of encapsulating the LED in a high-index medium, which significantly improves light extraction efficiency (LEE) from the LED.

LED contacts could be formed prior to fabricating the waveguide or afterwards by tracing over the waveguide sidewall and contacting the LED through a via, using either reflective or transparent conductive materials.

FIG. 8c shows a corresponding top view of a parabolic reflector 821 used to couple light from an LED, which may be the microLED 813, into a 1D array of output waveguides. The array of output waveguides includes a plurality of waveguide cores 823 surrounded by waveguide cladding 825. The intensity distribution at the waveguide inputs is somewhat complicated because there is overlap of reflected and unreflected rays. There is also a contribution from the lateral emission. The power into each waveguide can be equalized by varying the waveguide area in inverse proportion to the optical intensity at its input.

LEDs are made from high-index materials (n>2.5) and emit light into a very large angular cone. When emitting into an external low-index medium such as air, this causes much of the light emanating from the LED's active layer to experience total internal reflection (TIR) at the LED-external medium interface and thus not be available to the external system; the fraction of emitted light that can be externally extracted is the light extraction efficiency (LEE).

There are numerous techniques for reducing TIR and thus increasing LEE, including roughening the LED surface and utilizing novel LED shapes. One of the most effective techniques for increasing LEE may be encapsulation of the LED in a high-index medium, referred to as an encapsulant. While the encapsulant index would ideally match that of the LED, an encapsulant simply may have an index significantly higher than that of the external medium. For instance, if the external medium is air with an index of n=1, an encapsulant with an index of 1.5 will significantly increase LEE.

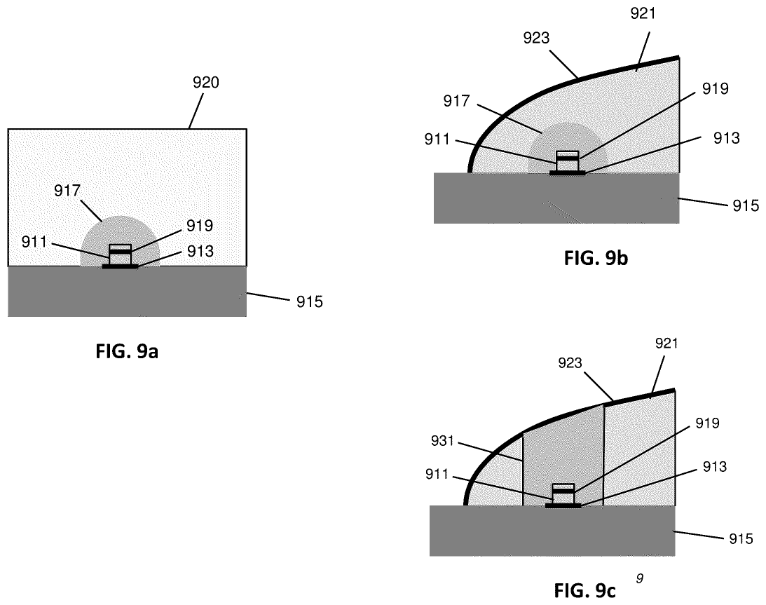

Note that the encapsulant does not provide TIR reduction benefits if the encapsulant-external medium interfaces are parallel to the LED-encapsulant interfaces. Rather, the encapsulant-external medium interface is ideally a spherical surface centered on the LED's active area. FIG. 9a shows an LED 911 with a rear reflector/contact 913 on a substrate 915. An encapsulant 917 also on the substrate encapsulates the LED. An outer edge of the encapsulant includes a rounded top, and is roughly equidistant from an active layer 919 of the LED. An air or other low index medium 920 is about the encapsulant.

This encapsulation technique can be applied to all of the microLED coupling schemes discussed above. This includes the planar waveguide scheme of FIGS. 8a-c, where the microLED is encased in the waveguide. In that case, as somewhat shown in FIG. 9b, the encapsulant is interposed between the microLED and waveguide medium. FIG. 9b shows a side view in which the LED 911 with a rear reflector/contact 913 is on a substrate 915. An encapsulant 917 also on the substrate encapsulates the LED. An outer edge of the encapsulant includes a rounded top, and is roughly equidistant from an active layer 919 of the LED. The encapsulant is in a waveguide medium 921, which has a parabolic-shaped end, in which the LED is located. A parabolic reflector 923 is over the parabolic-shaped end of the waveguide medium.

This has the ancillary benefit of mechanically isolating the LED from any stress in the waveguide medium. For instance, in some embodiments a polymer encapsulant can be used to isolate the LED from a high-stress oxide waveguide.

For the waveguide example of FIGS. 8a-c, the encapsulant can also be an approximately cylindrical column 931 that continues up to the top of the waveguide, as shown in FIG. 9c. If the top of the waveguide is part of a parabolic reflector, the reflection from that top surface will be approximately parallel to the encapsulant-waveguide medium interface and the reflections at that interface will be minimized.

Various technologies can be used to implement the foregoing schemes. In some embodiments the waveguides and lens could be made of a combination of polymer, oxide, nitride, or other inorganic materials. Lens geometry could be controlled by thermal reflow, by multi-layer two-dimensional lithography, or by three-dimensional lithography.

A deep parabolic structure is used in some of the foregoing schemes. Such a deep structure with a controlled sidewall curvature could be obtained by a combination of anisotropic and isotropic etching steps. For example, on a silicon substrate, or its oxide, the deep parabolic shape could be obtained by a combination of dry deep reactive-ion (DRIE), wet potassium hydroxide (KOH), hydrofluoric acid-based wet etching. The trench could be filled to the appropriate height by the transparent cladding material upon which an LED would be placed. The LED and trench could be filled with the cladding material to provide a robust surface upon which to produce a lens or other structure.

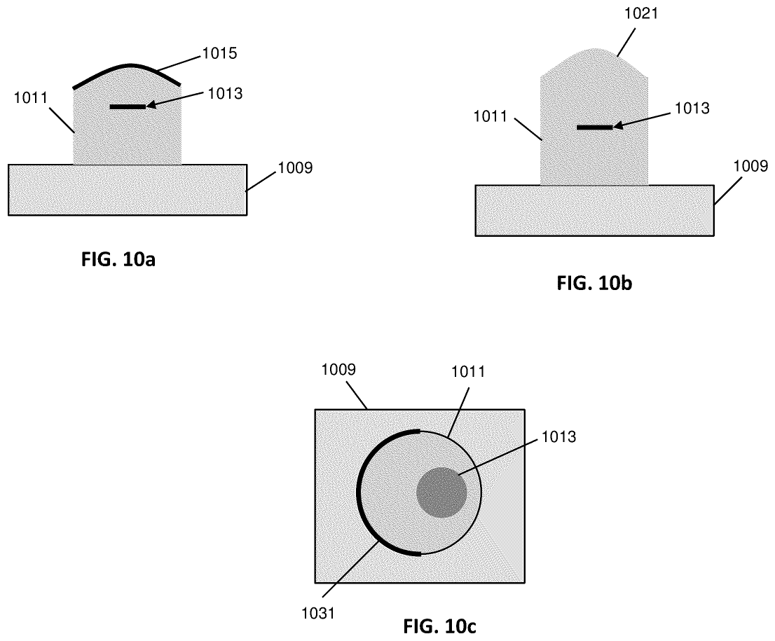

Reflectors and lenses can be formed on the LEDs themselves. These techniques are generally most useful if the active layer region of the LED does not extend all the way to the edge of the device. FIG. 10a shows a curved reflector formed on one end of a microLED. The microLED is on a substrate 1009. The microLED includes a body 1011, with an active layer 1013 in the body. The curved reflector 1015 is on a curved end surface of the body, concave towards the active layer. This can be used to reduce the angular spread of the light from the LED and reflect it back through a transparent substrate. FIG. 10b shows an embodiment similar to that of FIG. 10a, except a lens 1021 is formed on the end of a microLED in place of the curved reflector. Use of the lens can reduce the angular spread of the light emitted by the LED. FIG. 10c shows a top view of a microLED mounted on a substrate. A curved reflector 1031 is fabricated on a side of the LED, which collects light emitted toward the reflector and reflects it forward with a reduced angular spread.

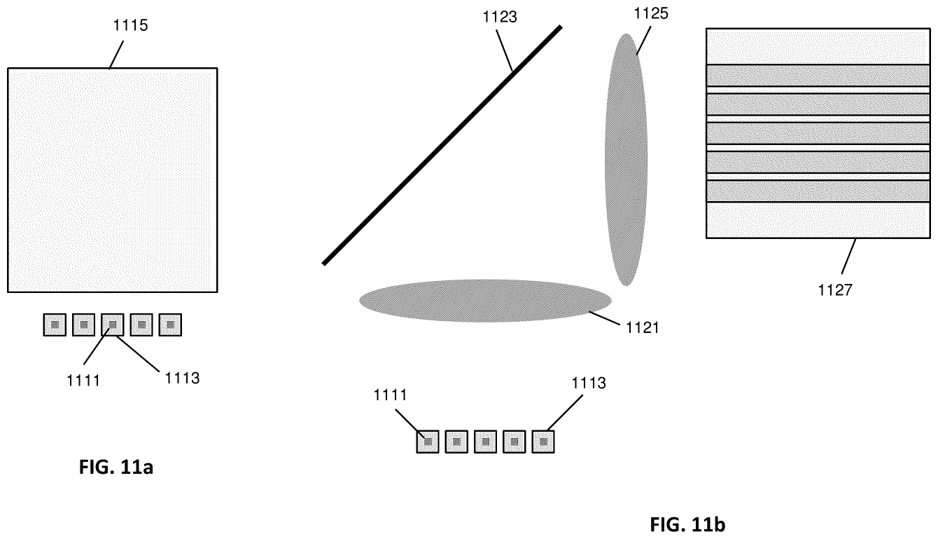

A single free-space optical element (FSOE) can operate on a large array of optical signals. FSOEs elements can be refractive, diffractive, and absorptive. Prominent examples of FSOEs include lenses, mirrors, gratings, and holographic optical elements. FIG. 11a shows an array of microLEDs 1111, each with its associated coupling assembly 1113, coupled into a free-space propagation region 1115, which may include free-space optics. The microLED coupling assembly may exploit any of the schemes enumerated above.

FIG. 11b shows a simple example of the free-space optical elements (FSOEs) that might make up a free-space propagation region. In FIG. 11b, light from an array of microLED coupling assemblies 1113 propagates, in sequence, to a lens 1121 that spans the entire array, a turning mirror 1123, and another lens 1125 that images the light from the entire microLED array onto a multi-waveguide array 1127. Examples of multi-waveguide arrays include multicore fibers, coherent imaging fibers, and multi-layer planar waveguide arrays.

In some embodiments the various arrangements including microLEDs is used in systems providing optical communications between chips and/or chiplets. In some embodiments, for example, the arrangements may be utilized in conjunction with an integrated circuit (IC).

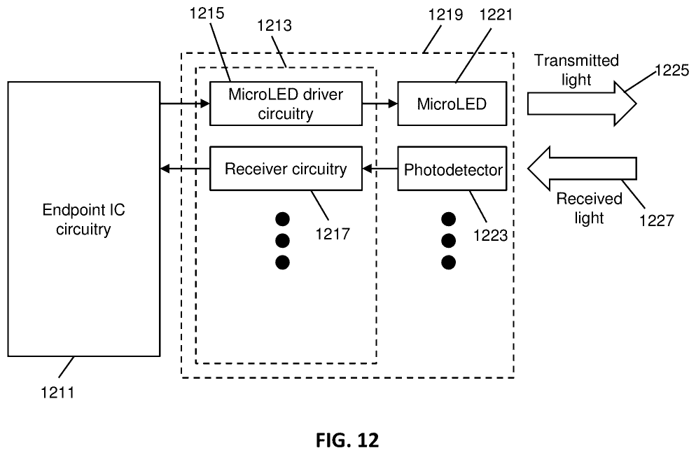

FIG. 12 is a block diagram showing an electrical architecture including a first optically-interconnected IC. The IC includes IC circuitry 1211 for performing logic and/or other functions. Transceiver circuitry 1213 is coupled to the IC circuitry. The transceiver circuitry comprises, and in some embodiments consists of, an array of microLED driver circuitry 1215 and an array of receiver circuitry 1217. The transceiver circuitry is part of a transceiver subsystem 1219. The transceiver subsystem also includes an array of microLEDs 1221 and photodetectors 1223. In some embodiments the transceiver circuitry may be monolithically integrated into the same IC containing the endpoint IC circuitry. In some embodiments the transceiver circuitry or may be contained in one or more separate transceiver ICs. The microLED driver circuitry drives the array of microLEDs to emit light 1225 to carry information provided to the driver circuitry from the endpoint IC circuitry. An N-bit wide unidirectional parallel bus connection may be implemented with N optical links from the transceiver subsystem to a second IC (not shown in FIG. 12), or, in some embodiments, a plurality of second ICs. A corresponding unidirectional parallel bus may be implemented by adding N additional optical links from the transceiver subsystem of the second IC to the transceiver subsystem of the first IC. The photodetectors receive light 1227 from the corresponding parallel bus, the light carrying information from the second IC. The photodetectors provide electrical signals carrying the received information to the receiver circuitry, which processes the signals and provides the information to the endpoint IC circuitry.

The optoelectronic (OE) devices, for example the microLEDs and photodetectors, may include structures that enhance optical coupling efficiency. For instance, microLEDs may include various structures that improve the light extract efficiency (LEE), including surface roughening, particular LED shapes, and encapsulation in high-index materials. They may also include structures such mirrors and lenses that collect the light from the LED's large intrinsic emission solid angle into a smaller solid angle that is better matched to the numerical aperture of the rest of the optical link. MicroLEDs are amenable to this reduction of angular cone due to their small size and thus relatively small etendue.

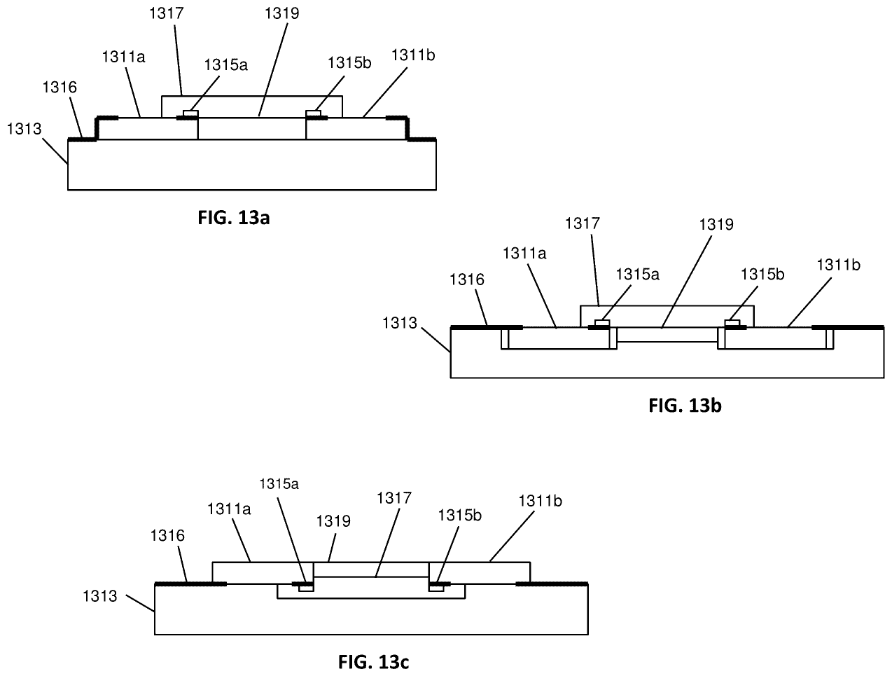

The transceiver subsystem can be implemented in a number of different physical configurations, for example as illustrated in FIGS. 13a-c. The configurations include a substrate, which may be rigid or flexible. Rigid substrate materials include silicon, glass, and laminates that include epoxy or resin. Flexible substrates may be made from various polymers.

In FIG. 13a, a first transceiver IC 1311a is mounted to the top of a substrate 1313 with an active side facing up. A first OE device 1315a is on top of the transceiver IC. The first transceiver IC in some embodiments is a very thin “micro-IC” that is only a few tens of microns thick. Electrical connections from a first endpoint IC (not shown in FIG. 13a) to the first transceiver IC are made by deposited metal traces 1316 that traverse the top of the substrate, and the side and top surfaces of the first transceiver IC. The first OE device is shown on the active side of the first transceiver IC. The first OE device receives signals from and/or provides signals to the first transceiver IC. The first OE device is shown as embedded or encapsulated in a waveguide core 1317. The waveguide core extends to a second transceiver IC 1311b, with waveguide cladding 1319 being shown as on top of the substrate between the first and second transceiver ICs. A second OE device 1315b is shown as on an active side of the second transceiver IC, with the second OE device also shown as embedded or encapsulated in the waveguide core. The second transceiver IC and the second OE may be as discussed with respect to the first transceiver IC and the first OE. As with the first transceiver IC, the second transceiver IC has electrical connections from a second endpoint IC (not shown in FIG. 13a). The first and second transceiver ICs, OE devices, and waveguide therefore may provide for optical communications substantially between the first endpoint IC and the second endpoint IC.

In FIG. 13b, the transceiver ICs 1311a,b are placed in a cavity in the substrate 1313. A material may be used to fill any gaps between the ICs and the substrate. This, for example, allows planar electrical connections from the substrate to the ICs. As with FIG. 13a, the OE devices 1315a,b are on top of the transceiver ICs.

In FIG. 13c, the transceiver ICs 1311a,b are mounted to the substrate 1313 with their active sides facing down. Such may simplify electrical connections from the substrate to the transceiver ICs. In FIG. 13c, part of each of the transceiver ICs containing the OE devices 1315a,b hangs over a cavity in the substrate. The OE devices are on the bottom of the transceiver ICs, in the cavity in the substrate.

For the embodiments of FIGS. 13a-c, the wave guide cores may be an array of planar optical waveguides, for example comprised of a bottom cladding and an array of cores, each of which guides light from a microLED at one end to a photodetector at the other end. Alternatively, both a microLED and photodetector can be located at both ends of each waveguide. This enables bidirectional transmission through each waveguide, supporting a duplex link.

In the embodiments of FIGS. 13a-c, a waveguide cladding layer is deposited in an appropriate region of the substrate. A layer of waveguides cores is fabricated on top of (or below for FIG. 13c) the cladding layer in a manner such that each OE device is encased in a separate waveguide core.

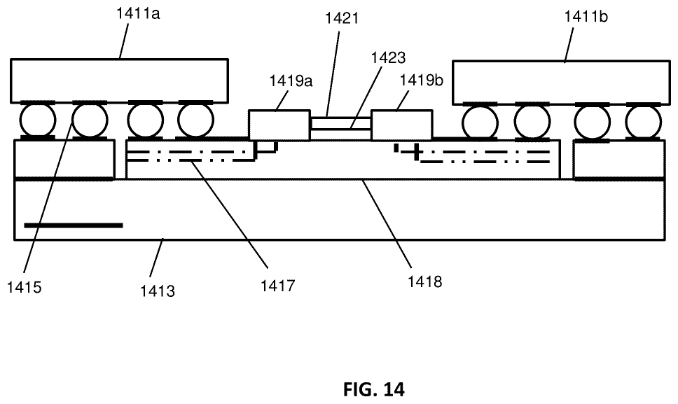

FIG. 14 shows integration of planar optical links within a package. A first endpoint IC 1411a is mounted to pads on a package 1413 by way of solder bumps 1415. Some pads connect to traces in metal signal layers 1417 of the package (or a substrate 1418 of the package), providing connection to a first transceiver subsystem 1419a. The first transceiver subsystem may be as discussed previously. One or more waveguide cores 1421 couple the first transceiver subsystem to a second transceiver subsystem 1419b, which may also be as discussed previously. For example, the waveguide cores may be separated from substrate by waveguide cladding 1423. The second transceiver subsystem is connected to a second endpoint IC 1411b, also by traces in metal signal layers of the package (or a substrate of the package). In FIG. 14, the metal signal layers of the package do not provide for electrical communications between the first endpoint IC and the second endpoint IC, although in some embodiments such may be additionally provided.

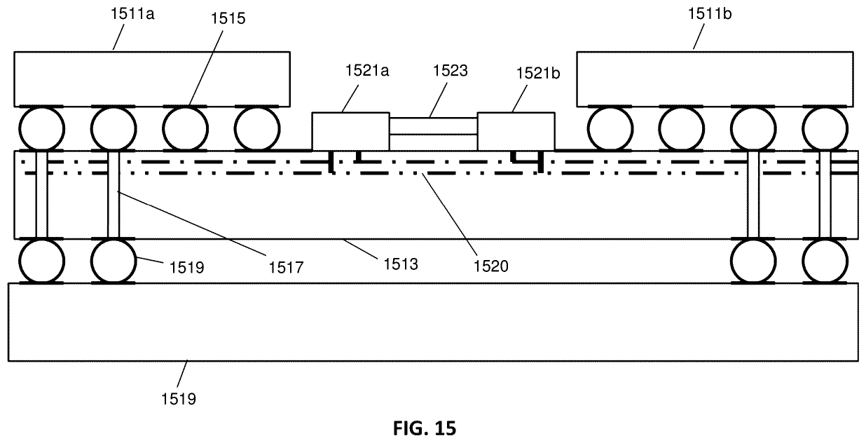

FIG. 15 shows the integration of planar optical links within an interposer and package. A first endpoint IC 1511a is mounted to pads on the interposer 1513 with solder bumps 1515. Some of the pads connect to through-substrate vias (TSVs) 1517 that, in turn, connect to the package 1519 via solder bumps. Other pads of the interposer connect to traces in metal signal layers 1520 of the interposer providing connection to a first transceiver subsystem 1521a. The first transceiver subsystem may be as discussed previously. One or more waveguide cores 1523 couple the first transceiver subsystem to a second transceiver subsystem 1521b, which may also be as discussed previously. The second transceiver subsystem is connected to a second endpoint IC 1511b, also by traces in metal signal layers of the interposer. In FIG. 15, the metal signal layers of the interposer provide for electrical communications between the first endpoint IC and the second endpoint IC, although in some embodiments such is not provided.

Although the invention has been discussed with respect to various embodiments, it should be recognized that the invention comprises the novel and non-obvious claims supported by this disclosure.

1. A system optically coupling two integrated circuit chips, the system including transceiver circuitry for each of the two integrated circuit chips, the system including optical elements comprising:
a microLED to be driven by the transceiver circuitry;
a photodetector to provide electrical signal carrying received information to the transceiver circuitry; and
an array of multiple waveguide cores, including a plurality of waveguide cores configured to receive light emitted by the microLED; and
a parabolic reflector;
wherein the microLED is positioned at a focus of the parabolic reflector, and the plurality of waveguide cores are positioned so as to receive light from the microLED reflected by the parabolic reflector.

2. (canceled)

3. The system including optical elements of claim 1, further comprising a back reflector on the microLED.

4. The system including optical elements of claim 1, further comprising a first lens in an optical path between the microLED and the plurality of waveguide cores.

5. The system including optical elements of claim 4, further comprising a turning mirror in an optical path between the first lens and the plurality of waveguide cores.

6. The system including optical elements of claim 5, further comprising a second lens in an optical path between the turning mirror and the plurality of waveguide cores.

7. The system including optical elements of claim 1, further comprising encapsulant surrounding the microLED.

8. The system including optical elements of claim 7, wherein the encapsulant has outer edges approximately equidistant from an active layer of the microLED.

9. The system including optical elements of claim 7, wherein the encapsulant forms a cylindrical column.

10.-14. (canceled)
